(19) United States
(12) Patent Application Publication
(10) Pub. No.: US 2025/0046612 A1
(43) Pub. Date: Feb. 6, 2025

(54) SEMICONDUCTOR DEVICE AND METHOD OF MANUFACTURING THE SAME

(71) Applicant: Renesas Electronics Corporation, Tokyo (JP)

(72) Inventors: Tadashi YAMAGUCHI, Tokyo (JP); Shinji INOUE, Tokyo (JP)

(21) Appl. No.: 18/776,808

(22) Filed: Jul. 18, 2024

(30) Foreign Application Priority Data
Aug. 3, 2023 (JP) 2023-126951

(51) Int. Cl. H01L 21/04; H01L 29/16; H01L 29/66; H01L 29/78

(52) U.S. Cl. CPC H01L 21/049; H01L 29/1608; H01L 29/66068; H01L 29/7813

(57) ABSTRACT

The reliability of a semiconductor device is improved. In this disclosure, a gate insulating film is formed on a silicon carbide semiconductor substrate in a process using a material gas containing a halogen element and a metal element by an ALD method.

### CROSS-REFERENCE TO RELATED APPLICATIONS

The disclosure of Japanese Patent Application No. 2023-126951 filed on Aug. 3, 2023, including the specification, drawings and abstract is incorporated herein by reference in its entirety.

### BACKGROUND

The present invention relates to a semiconductor device and its manufacturing technology, for example, a technology effective when applied to the semiconductor device and its manufacturing technology that includes a semiconductor substrate composed of a wide bandgap semiconductor material with a larger bandgap than silicon.

Japanese Patent Laid-Open No. 2017-228679 (Patent Document 1) describes a technology for improving a reliability of a semiconductor device including a SiC power transistor.

### SUMMARY

In order to improve a performance of the semiconductor device including a field effect transistor, it is considered to manufacture the semiconductor device using the semiconductor substrate composed of the wide bandgap semiconductor material with a larger bandgap than silicon.

However, with the current technology, a gate insulating film formed on the semiconductor substrate composed of the wide bandgap semiconductor material does not have as high reliability as a silicon oxide film formed on a silicon substrate. Therefore, in the semiconductor device manufactured using the semiconductor substrate composed of the wide bandgap semiconductor material, it is desired to form the gate insulating film with high reliability.

Other objects and novel features will become apparent from the description of this specification and the accompanying drawings.

A method of manufacturing the semiconductor device according to one embodiment includes a step of forming the gate insulating film on the semiconductor substrate composed of the wide bandgap semiconductor material with the larger bandgap than silicon. In this step, the gate insulating film is formed by a chemical vapor deposition method using a material gas containing a halogen element and a metal element.

The semiconductor device according to one embodiment includes the field effect transistor having the gate insulating film formed on the semiconductor substrate composed of the wide bandgap semiconductor material with the larger bandgap than silicon. Here, the gate insulating film has the halogen element with a higher concentration than carbon. According to one embodiment, the reliability of the semiconductor device can be improved.

### BRIEF DESCRIPTION OF THE DRAWINGS

FIG. 1 is a flowchart explaining an ALD method used in the embodiment.

FIG. 2 is a figure qualitatively explaining a mechanism in which the amount of moisture contained in a gate insulating film increases in the ALD method using trimethylaluminum.

FIG. 3 is a figure qualitatively explaining a mechanism in which the amount of moisture contained in the gate insulating film decreases in the ALD method using aluminum trichloride.

FIG. 4 is a graph showing the measurement results of the amount of moisture based on the temperature rise desorption method.

FIG. 5 is a graph showing the results of measuring the carbon concentration in the gate insulating film by SIMS analysis.

FIG. 6 is a graph showing the results of measuring the chlorine concentration in the gate insulating film by SIMS analysis.

FIG. 7 is a plot showing the relationship between the silicon oxide equivalent film thickness of the gate insulating film and the amount of traps present in the gate insulating film.

FIG. 8 is a plot showing the relationship between the silicon oxide equivalent film thickness of the gate insulating film and the leakage current density flowing through the gate insulating film.

FIG. 9 is a figure showing an example of the structure of an aluminum oxide film formed by using trimethylaluminum as a material for the ALD method.

FIG. 10 is a diagram showing an example of the structure of an aluminum oxide film formed by using aluminum trichloride as a material for the ALD method.

FIG. 11 is a cross-sectional view showing the structure of a semiconductor device including a planar SiC field effect transistor.

FIG. 12 is a flowchart showing the manufacturing process of the semiconductor device in Application Example 1.

FIG. 13 is a flowchart showing the manufacturing process of the semiconductor device in Application Example 1.

FIG. 14 is a cross-sectional view showing the structure of the semiconductor device that includes a trench gate type SiC field effect transistor.

### DETAILED DESCRIPTION

In all the drawings for explaining the embodiments, the same members are denoted by the same reference numerals in principle, and repetitive descriptions thereof are omitted. Note that even plan view may be hatched for the sake of clarity.

Attention has been paid to a semiconductor device (hereinafter referred to as a wide bandgap power semiconductor device) that includes a field effect transistor formed on a semiconductor substrate mainly composed of a semiconductor material with a larger bandgap than silicon.

This is because the larger bandgap means that it has a high dielectric breakdown strength, making it easier to achieve high withstand voltage.

And if the semiconductor material itself has a high dielectric breakdown strength, it is possible to ensure the breakdown voltage even if the drift layer that maintains the breakdown voltage is thin. From this, for example, by thinning the drift layer and increasing the impurity concentration, the on-resistance of the power semiconductor device can be reduced. In other words, the wide bandgap power semiconductor device is excellent in that it can balance the improvement of breakdown voltage, which is in a trade-off relationship with each other, and the reduction of on-resistance. Therefore, the wide bandgap power semiconductor device is expected as the semiconductor device that can achieve high performance.

Examples of semiconductor materials with the larger bandgap than silicon include silicon carbide (SiC), gallium nitride (GaN), gallium oxide (Ga₂O₃), and diamond. Hereinafter, we will focus on silicon carbide.

### (Improvement Consideration)

In a field effect transistor (hereinafter referred to as a Si field effect transistor) having a gate insulating film formed on a silicon substrate, the gate insulating film is composed of a silicon oxide film formed by a thermal oxidation method, for example. The gate insulating film formed in this way is a high-quality film with high reliability. That is, in the Si field effect transistor, the gate insulating film can be composed of a high-quality film with high reliability.

On the other hand, in a field effect transistor (hereinafter referred to as a SiC field effect transistor) having a gate insulating film formed on a silicon carbide substrate, the gate insulating film is composed of a silicon oxynitride film (SiON) formed using NO gas or N₂O gas, for example. However, it is known that it is difficult to make the gate insulating film formed in this way a film with high reliability.

Specifically, in the method of forming the gate insulating film described above, a silicon oxynitride film is formed while cutting the Si—C bond of silicon carbide by an oxidation reaction. For this reason, interface defects (dangling bonds) are formed at the interface between SiON and SiC. As a result, the density of interface defect levels in the gate insulating film is high. This may cause an increase in the on-resistance of the semiconductor device and a shift in the threshold voltage. Thus, in the SiC field effect transistor, it is difficult to compose the gate insulating film from a high-quality film.

Therefore, a method of forming the gate insulating film using the chemical vapor deposition method (CVD method) that deposits a film on the silicon carbide substrate, not by a thermal oxidation method, has been proposed. This method is not a method of forming a gate insulating film while cutting the Si—C bond of silicon carbide, so it is considered that the interface defect level can be reduced.

However, the deposited film formed by the CVD method may inherently contain elements derived from the raw material as impurities in the deposited film along with moisture due to its film formation principle. That is, in the gate insulating film formed by the CVD method, the fact that moisture and impurities derived from the raw material are included as impurities is manifested as room for improvement.

In this regard, the present inventors have acquired the following new findings.
(1) Moisture contained in the gate insulating film can migrate to the interface and cause oxidation reactions, leading to the generation of interface defect levels. Therefore, it is desirable to remove the moisture contained in the gate insulating film. Moisture can be removed by annealing (heat treatment).
(2) In case of carbon being included in a raw material gas of the CVD method, carbon is included in the gate insulating film. Carbon does not desorb from the gate insulating film even when annealed, and can cause degradation of the film quality of the gate insulating film. Therefore, it is desirable to reduce the carbon contained in the gate insulating film.
(3) In case of a halogen element being included in the raw material gas of the CVD method, the halogen element is included in the gate insulating film. The halogen element does not desorb from the gate insulating film even when annealed. However, even if the halogen element is included in the gate insulating film, they are less likely to degrade the film quality.

Based on the above findings, the inventors of the present invention have found a technical idea that can form the gate insulating film with high reliability in a method of forming the gate insulating film by the CVD method. The technical idea found by the inventors will be described below.

### (Basic Idea in the Embodiment)

The basic idea in the present embodiment is to form the gate insulating film on the silicon carbide substrate using a CVD method with the material gas containing the halogen element and the metal element. According to this basic idea, the material gas of the CVD method contains the halogen element. As a result, the gate insulating film contains the halogen element. However, even if the halogen element is included in the gate insulating film, there is less risk of degrading the film quality. Therefore, according to the basic idea, the gate insulating film can be formed from a film with high reliability.

In other words, according to the basic idea, a CVD method is used that deposits a film without breaking Si—C bonds, rather than a thermal oxidation method that forms a film while breaking Si—C bonds. Therefore, the interface defect level can be reduced. And since the material gas containing the halogen element that is less likely to degrade the film quality of the gate insulating film is used as the material gas of the CVD method, the film quality can be improved.

In other words, in the basic idea, a high-quality gate insulating film can be formed by the combination of (1) using a CVD method that can suppress the generation of interface defect levels, and (2) using the material gas containing the halogen element as the material gas of the CVD method.

Examples of the halogen element include fluorine or chlorine. Examples of the metal element includes aluminum (Al), hafnium (Hf), or zirconium (Zr). For example, aluminum is used when forming the gate insulating film from an aluminum oxide film (alumina film). Hafnium is used when forming the gate insulating film from a hafnium oxide film (hafnia film), and zirconium is used when the gate insulating film is formed from a zirconium oxide film.

Thus, in the basic idea, the material gas containing the halogen element and the metal element is used as the material gas of the CVD method. Furthermore, it is desirable that the material gas of the CVD method does not contain carbon and hydrogen. This is because carbon can cause degradation of the film quality of the gate insulating film. Also, if the material gas of the CVD method contains hydrogen, the gate insulating film is likely to contain moisture, a compound of hydrogen and oxygen. Moisture can migrate to the interface and cause oxidation reactions, leading to the generation of interface defect levels. Therefore, it is desirable to use the material gas that contains the halogen element and the metal element but does not contain carbon and hydrogen as the material gas of the CVD method, based on the aforementioned new findings (1), (2), and (3).

Furthermore, although it is not a requirement, it is desirable to have a process of heating the silicon carbide substrate after forming the gate insulating film. As explained in the novel finding (1) mentioned above, the gate insulating film formed by the CVD method contains moisture. This moisture moves to the interface and causes an oxidation reaction, which is the cause of the formation of interface defect levels. Therefore, in order to form the high-quality gate insulating film, it is desirable to remove the moisture contained in the gate insulating film. For this reason, it is desirable to heat the silicon carbide substrate to remove moisture from the gate insulating film.

At the silicon carbide interface, in order for the silicon carbide not to be oxidized by the reaction with the moisture that has departed, it is desirable that a heating temperature (annealing temperature) is lower than 900 degrees Celsius. This is because the temperature at which the oxidation of silicon carbide begins is 900 degrees Celsius. In other words, in order to remove moisture from the gate insulating film, it is effective that the temperature range is such that the moisture that has departed from the gate insulating film does not react with silicon carbide.

Also, in order to remove moisture from the gate insulating film, it is desirable that the heating temperature of the silicon carbide substrate is higher than a formation temperature of the gate insulating film. The heating temperature of the silicon carbide substrate is, for example, a temperature of 500 degrees Celsius or higher and less than 900 degrees Celsius.

According to the basic idea as described above, even the gate insulating film formed on the silicon carbide substrate can form the gate insulating film with high reliability.

In the following, a realization mode embodying the basic idea will be described.

### Embodiment

### (A Manufacturing Method of the Semiconductor Device)

In the embodiment, a process of forming the gate insulating film included in a manufacturing method of the semiconductor device is described. In particular, in the embodiment, an example of constructing the gate insulating film formed on the silicon carbide substrate from an aluminum oxide film (Al₂O₃ film) is explained. Also, an example of using Atomic Layer Deposition method (hereinafter, referred to as ALD method), a type of CVD method, as a film formation method for the gate insulating film is explained.

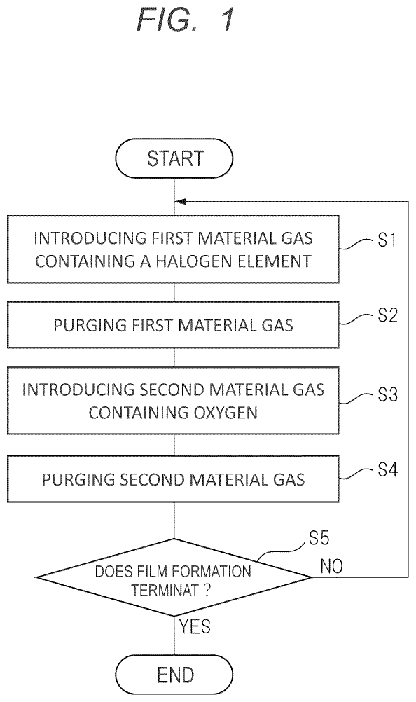

FIG. 1 is a flowchart explaining the ALD method used in the embodiment.

In FIG. 1, first, a first material gas containing a halogen element is introduced onto the silicon carbide substrate on which the gate insulating film is to be formed (S1). Then, the first material gas is purged (S2). Next, a second material gas containing oxygen is introduced onto the silicon carbide substrate (S3). Then, the second material gas is purged (S4). By going through such a process, the gate insulating film with an atomic layer level film thickness can be formed on the silicon carbide substrate. If the gate insulating film with a predetermined film thickness has not been formed, the film formation treatment is continued (S5). On the other hand, when the gate insulating film with a predetermined film thickness is formed, the film formation treatment is terminated (S5). In this way, the gate insulating film with a desired film thickness can be formed.

Here, the first material gas is AlCl₃. Also, the second material gas is either H₂O, O₃, or N₂O. And, the film formation temperature in the ALD method is, for example, 25 degrees Celsius or more and 400 degrees Celsius or less. By using such the ALD method, according to the embodiment, the gate insulating film with high reliability can be formed. That is, in the embodiment, by using AlCl₃ as the first material gas containing a halogen element in the ALD method, the following characteristic points can be obtained. With this characteristic point, according to the embodiment, the gate insulating film with high reliability can be formed.

The above-mentioned characteristic points will be explained below.

The first characteristic point in the embodiment is that by using AlCl₃, the amount of moisture present in the gate insulating film can be reduced. For example, when forming the gate insulating film from an aluminum oxide film, generally, trimethylaluminum (Al(CH₃)₃) is used as the material gas of the ALD method. In this regard, the present inventors have newly found that when trimethylaluminum is used, the amount of moisture contained in the gate insulating film increases.

Therefore, considering that the moisture contained in the gate insulating film becomes the cause of the generation of interface defect levels, it becomes difficult to form the gate insulating film with high reliability when using trimethylaluminum.

On the other hand, the present inventors have newly found that when AlCl₃ is used as the material gas of the ALD method, the amount of moisture contained in the gate insulating film can be reduced compared to when trimethylaluminum is used. From this, if AlCl₃ is used, the moisture in the gate insulating film, which is the cause of the generation of interface defect levels, can be reduced. Therefore, by using AlCl₃, the gate insulating film with high reliability can be formed.

Below, a qualitative mechanism in which the amount of moisture contained in the gate insulating film increases when trimethylaluminum is used, and the amount of moisture contained in the gate insulating film decreases when AlCl₃ is used, will be explained.

The ALD method when using trimethylaluminum has the following steps. (a1) A step of introducing trimethylaluminum. (a2) A step of purging trimethylaluminum. (a3) A step of introducing H₂O (oxidizing agent). (a4) A step of purging H₂O.

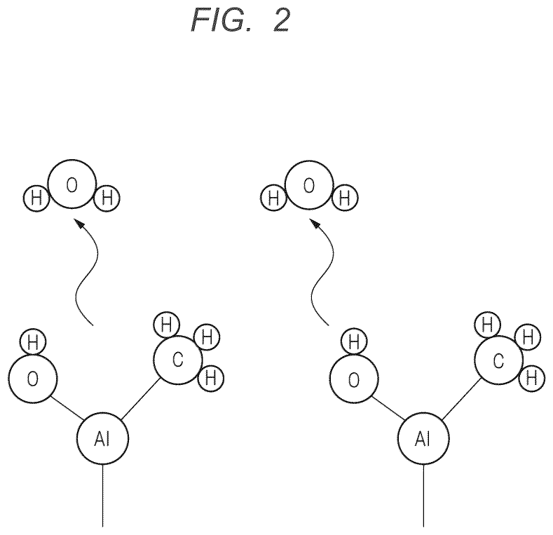

As a result, for example, as shown in FIG. 2, some of the methyl groups of trimethylaluminum are replaced with hydroxyl groups by the oxidizing agent (H₂O). Then, the hydrogen constituting the methyl group and the hydroxyl group react to generate and detach moisture. In this manner, in trimethylaluminum, hydrogen, which is a constituent element of moisture, is present, making it easy to generate moisture. As a result, when using trimethylaluminum, the amount of moisture contained in the gate insulating film tends to increase.

In contrast, the ALD method using AlCl₃ has the following steps. (a1) A step of introducing AlCl₃. (a2) A step of purging AlCl₃. (a3) A step of introducing H₂O (oxidizing agent). (a4) A step of purging H₂O.

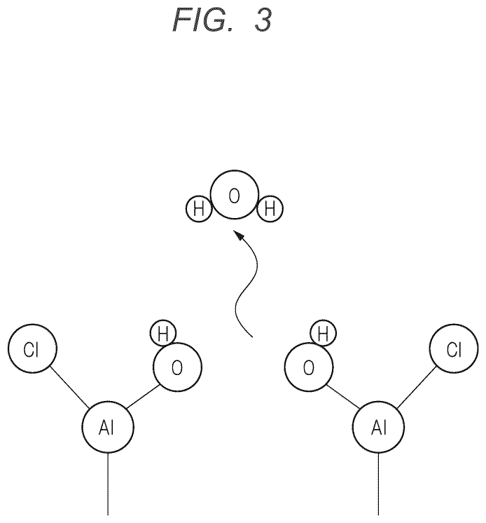

Thus, for example, as shown in FIG. 3, some of the chlorine in AlCl₃ is replaced by hydroxyl groups by the oxidizing agent (H₂O). Then, moisture is generated and desorbed by the reaction of a plurality of hydroxyl groups. In this regard, in AlCl₃, since there is no hydrogen, which is a constituent element of moisture, it is difficult to generate moisture. As a result, when using AlCl₃, it becomes easier to reduce the amount of moisture contained in the gate insulating film.

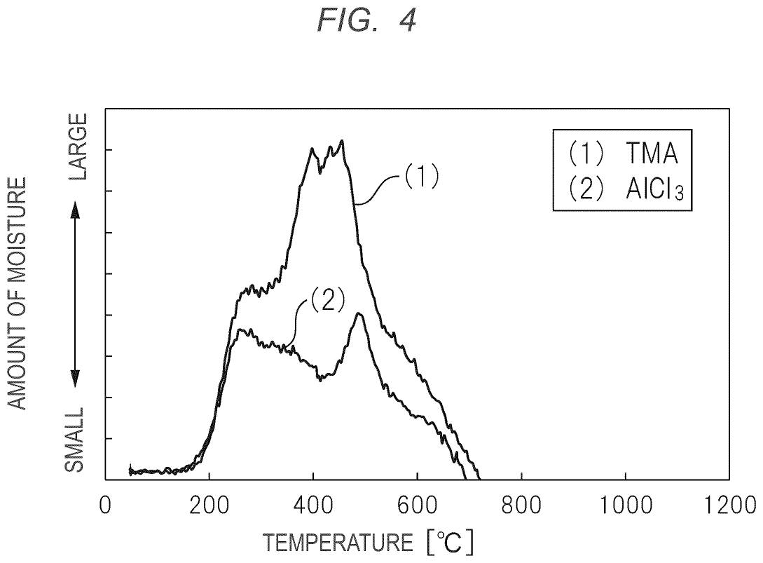

FIG. 4 is a graph showing the results of measuring the amount of moisture based on the temperature desorption method. In FIG. 4, the horizontal axis indicates the temperature of the stage where the silicon carbide substrate, which formed the gate insulating film (aluminum oxide film), is placed. On the other hand, the vertical axis indicates the amount of moisture contained in the gate insulating film.

Graph (1) shows an aluminum oxide film formed by the ALD method using trimethylaluminum (TMA) as the material gas. Graph (2) shows an aluminum oxide film formed by the ALD method using AlCl₃ as the material gas.

As shown in FIG. 4, it can be seen that the amount of moisture in the aluminum oxide film formed by the ALD method using AlCl₃ as the material gas is less than the amount of moisture in the aluminum oxide film formed by the ALD method using trimethylaluminum (TMA) as the material gas. Therefore, it has been confirmed that by using AlCl₃, the amount of moisture in the gate insulating film (in the aluminum oxide film) can be reduced compared to when using trimethylaluminum.

In addition, instead of H₂O, O₃ or N₂O can also be used as the oxidizing agent. In this case, the amount of moisture in the gate insulating film can be further reduced. This is because, while H₂O contains hydrogen, O₃ or N₂O does not contain hydrogen, which is a constituent element of moisture, resulting in less moisture generation in the gate insulating film. In other words, from the viewpoint of reducing the amount of moisture in the gate insulating film, it is desirable to use O₃ or NO as the oxidizing agent.

Next, the second characteristic point in the embodiment is that by using AlCl₃, the amount of carbon present in the gate insulating film can be reduced. That is, since AlCl₃ does not contain carbon, the amount of carbon contained in the gate insulating film can be reduced. In other words, considering that carbon can degrade the film quality of the gate insulating film, the fact that carbon can be reduced in the gate insulating film by using AlCl₃, which does not contain carbon, as the material gas in the ALD method leads to the formation of the gate insulating film with high reliability.

For example, trimethylaluminum contains carbon as a methyl group. Therefore, when using trimethylaluminum as the material gas in the ALD method, the amount of carbon contained in the gate insulating film increases. As a result, the film quality of the gate insulating film is degraded by carbon.

In contrast, as in the embodiment, when using AlCl₃, since AlCl₃ does not contain carbon, the amount of carbon contained in the gate insulating film can be reduced. As a result, according to the embodiment, the amount of carbon, which is a factor in the degradation of the film quality of the gate insulating film, can be reduced. From this, according to the embodiment, the gate insulating film with high reliability can be formed.

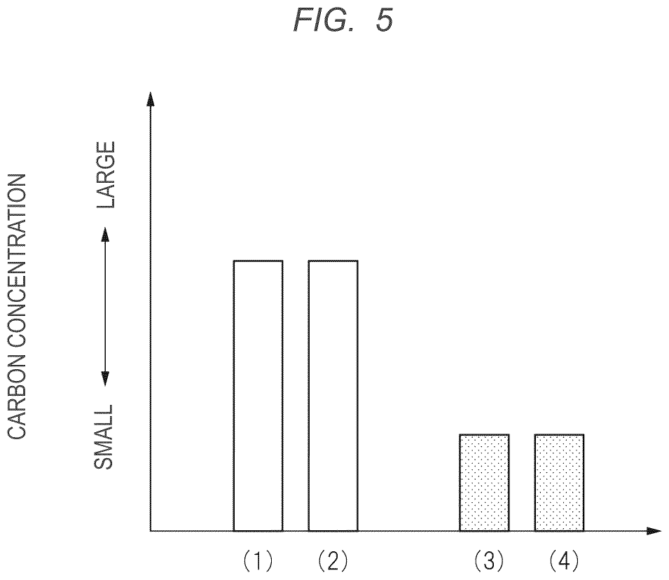

FIG. 5 is a graph showing the results of measuring the carbon concentration in the gate insulating film by SIMS analysis. In FIG. 5, graph (1) shows the gate insulating film formed using trimethylaluminum. Graph (2) illustrates the gate insulating film that underwent a heat treatment at 800 degrees Celsius after film formation using trimethylaluminum.

Furthermore, Graph (3) illustrates the gate insulating film formed using AlCl₃. Graph (4) illustrates the gate insulating film that underwent a heat treatment at 800 degrees Celsius after film formation using AlCl₃.

Firstly, as shown in FIG. 5, by using AlCl₃, the carbon concentration in the gate insulating film can be reduced compared to when using trimethylaluminum.

Here, even when AlCl₃, which does not contain carbon, is used as the material gas for the ALD method, it can be inferred from FIG. 5 that the gate insulating film contains a small amount of carbon. This can be attributed to the diffusion of carbon from the silicon carbide substrate in contact with the gate insulating film, as the gate insulating film is formed on the silicon carbide substrate.

Next, from FIG. 5, regardless of whether trimethylaluminum or AlCl₃ is used, the carbon concentration in the gate insulating film after a heat treatment at 800 degrees Celsius does not significantly change from the carbon concentration in the gate insulating film before the heat treatment. In other words, the carbon contained in the gate insulating film does not desorb, regardless of the type of the material gas used in the ALD method, even after a heat treatment at 800 degrees Celsius.

From this, it can be concluded that heat treatment is not an effective method for reducing the carbon content in the gate insulating film. On the other hand, adopting AlCl₃, which does not contain carbon, instead of trimethylaluminum, which does contain carbon, is effective from the perspective of reducing the carbon content in the gate insulating film, as in the embodiment.

Next, the third characteristic point in the embodiment is that the use of AlCl₃ results in a higher chlorine content in the gate insulating film. In other words, because AlCl₃ contains chlorine, the chlorine content in the gate insulating film increases.

However, chlorine does not cause degradation of the film quality of the gate insulating film. Considering this, using AlCl₃, which contains chlorine, as the material gas for the ALD method does not pose a problem for forming the gate insulating film with high reliability. Rather, the use of AlCl₃ is useful from the perspective of forming the gate insulating film with high reliability, as it can reduce the carbon content, which can cause degradation of the film quality of the gate insulating film.

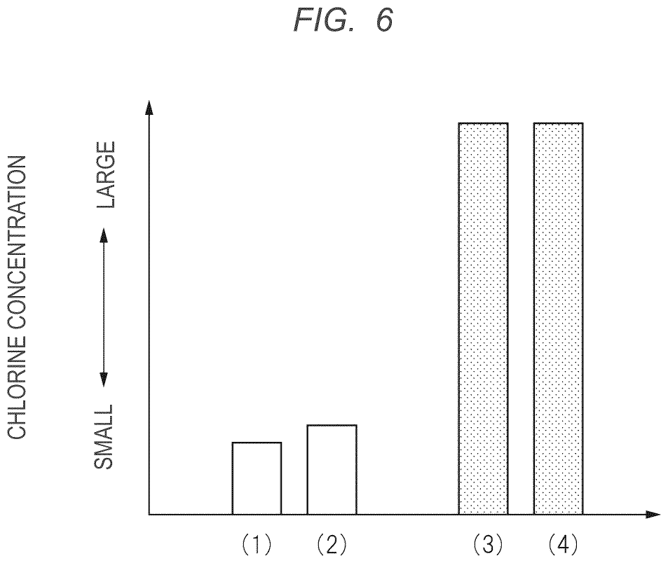

FIG. 6 is a graph showing the results of measuring the chlorine concentration in the gate insulating film by SIMS analysis. In FIG. 6, Graph (1) illustrates the gate insulating film formed using trimethylaluminum. Graph (2) illustrates the gate insulating film that underwent a heat treatment at 800 degrees Celsius after film formation using trimethylaluminum.

Furthermore, Graph (3) illustrates the gate insulating film formed using AlCl₃. Graph (4) illustrates the gate insulating film that underwent a heat treatment at 800 degrees Celsius after film formation using AlCl₃.

Firstly, as shown in FIG. 6, by using AlCl₃, the chlorine concentration in the gate insulating film can be increased compared to when using trimethylaluminum. This is because AlCl₃ contains chlorine, while trimethylaluminum does not.

Next, from FIG. 6, regardless of whether trimethylaluminum or AlCl₃ is used, the chlorine concentration in the gate insulating film after a heat treatment at 800 degrees Celsius does not significantly change from the chlorine concentration in the gate insulating film before the heat treatment. In other words, the chlorine contained in the gate insulating film does not desorb, regardless of the type of the material gas used in the ALD method, even after a heat treatment at 800 degrees Celsius. However, even if chlorine remains in the gate insulating film, it does not degrade the film quality of the gate insulating film. Therefore, the residual chlorine in the gate insulating film does not pose a problem from the perspective of forming the gate insulating film with high reliability.

From the above, according to the embodiment, the first, second, and third features mentioned above can be obtained by using AlCl₃. As a result, in the embodiment, these features enable the formation of the gate insulating film with high reliability.

### (Verification of Effect)

Hereinafter, the results of verification that substantiate the ability to form the gate insulating film with high reliability according to the embodiment will be described.

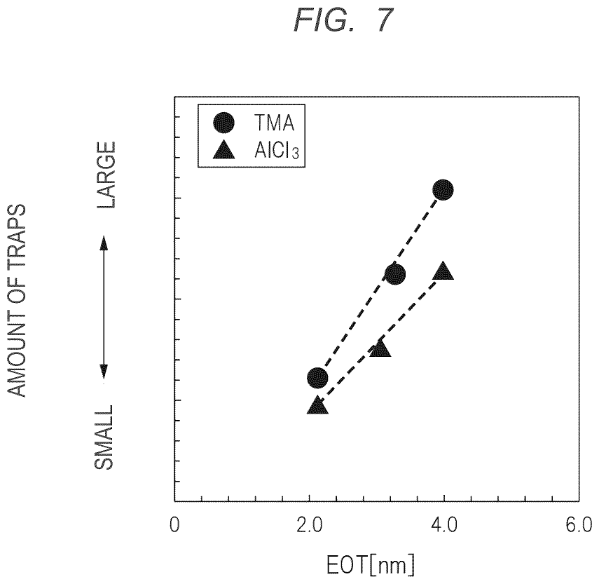

FIG. 7 is a plot showing the relationship between the equivalent oxide thickness (EOT) of the gate insulating film and the amount of traps present in the gate insulating film. The horizontal axis represents the equivalent oxide thickness. The vertical axis represents the amount of traps. In FIG. 7, the gate insulating film is an aluminum oxide film. Also, the circle mark is a plot indicating an aluminum oxide film formed by using trimethylaluminum. Furthermore, the triangle mark is a plot indicating an aluminum oxide film formed by using AlCl₃.

As shown in FIG. 7, the amount of traps in the aluminum oxide film formed by using AlCl₃ is smaller than the amount of traps in the aluminum oxide film formed by using trimethylaluminum. In other words, the defect level density in the aluminum oxide film formed by using AlCl₃ is smaller than the defect level density in the aluminum oxide film formed by using trimethylaluminum.

This means that the aluminum oxide film formed by using AlCl₃ is the gate insulating film with higher reliability than the aluminum oxide film formed by using trimethylaluminum. Therefore, from FIG. 7, it is confirmed that the aluminum oxide film (gate insulating film) formed by using AlCl₃ is the gate insulating film with high reliability.

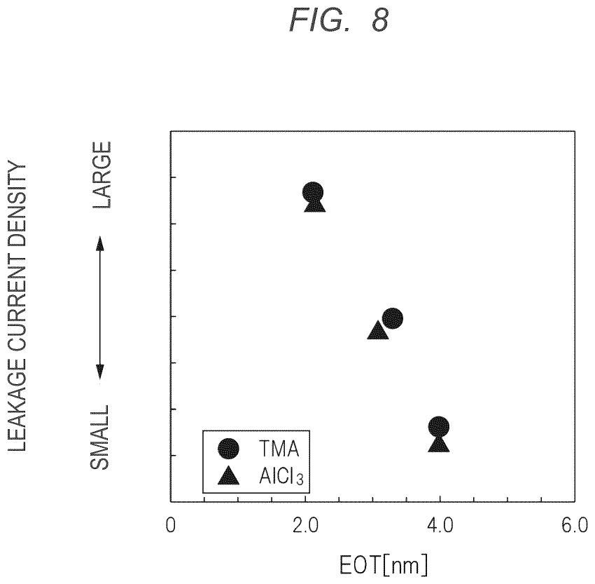

Next, FIG. 8 is a plot showing the relationship between the equivalent oxide thickness (EOT) of the gate insulating film and the leakage current density flowing through the gate insulating film. The horizontal axis represents the equivalent oxide thickness. The vertical axis represents the leakage current density.

In FIG. 8, the gate insulating film is an aluminum oxide film. Also, the circle mark indicates an aluminum oxide film formed by using trimethylaluminum. Furthermore, the triangle mark indicates an aluminum oxide film formed by using AlCl₃.

As shown in FIG. 8, the leakage current density in the aluminum oxide film formed by using AlCl₃ is smaller than the leakage current density in the aluminum oxide film formed by using trimethylaluminum.

This means that the aluminum oxide film formed by using AlCl₃ is the gate insulating film with higher reliability than the aluminum film formed by using trimethylaluminum. Therefore, from FIG. 8, it is confirmed that the aluminum oxide film (gate insulating film) formed by using AlCl₃ is the gate insulating film with high reliability.

Hereinafter, a qualitative mechanism will be described in which the amount of traps and the leakage current density become smaller in the aluminum oxide film formed by using AlCl₃ than in the aluminum oxide film formed by using trimethylaluminum.

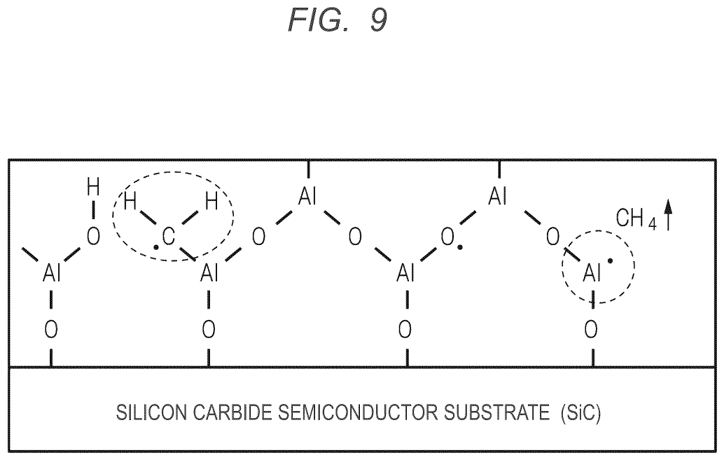

FIG. 9 is a diagram showing an example of the structure of an aluminum oxide film formed by using trimethylaluminum. As shown in FIG. 9, in the aluminum oxide film formed by using trimethylaluminum, “trap sites” are generated by the residue and departure of CHx. As a result, in the aluminum oxide film formed by using trimethylaluminum, the defect level density increases, resulting in an increase in the leakage current density.

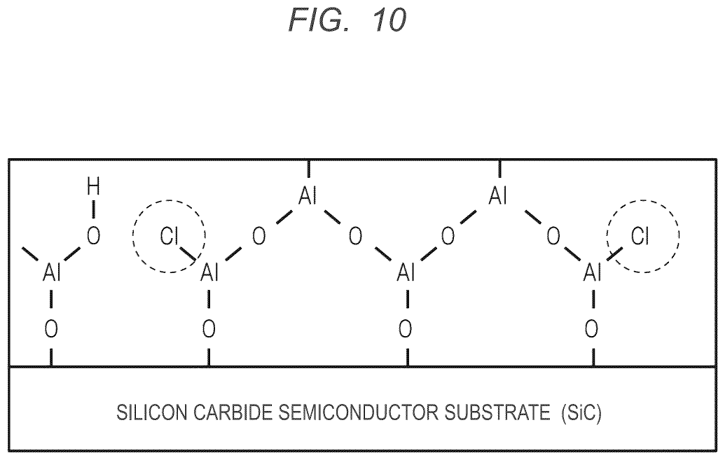

FIG. 10 is a diagram showing an example of the structure of an aluminum oxide film formed by using AlCl₃. As shown in FIG. 10, in the aluminum oxide film formed using AlCl₃, dangling bonds are terminated by chlorine (Cl). As a result, in the aluminum oxide film formed using AlCl₃, the defect level density decreases, resulting in a decrease in leakage current density.

Through such a mechanism, it can be qualitatively understood that the high-quality gate insulating film with a small defect level density and leakage current density can be realized in the aluminum oxide film formed by using AlCl₃.

### Application Example

According to the embodiment, the gate insulating film with high reliability can be formed. Therefore, by manufacturing a field effect transistor using the gate insulating film in the embodiment, the reliability of the semiconductor device including the field effect transistor can be improved.

Below, silicon carbide is mentioned as an example of a wide bandgap semiconductor material with the larger bandgap than silicon. And, as an application example of the gate insulating film in the embodiment, a SiC field effect transistor having the gate insulating film formed on the silicon carbide substrate is explained as an example. In particular, in Application Example 1, a semiconductor device including a planar type SiC field effect transistor is described. In Application Example 2, a semiconductor device including a trench gate type SiC field effect transistor is described.

### Application Example 1

### (Configuration of a Semiconductor Device)

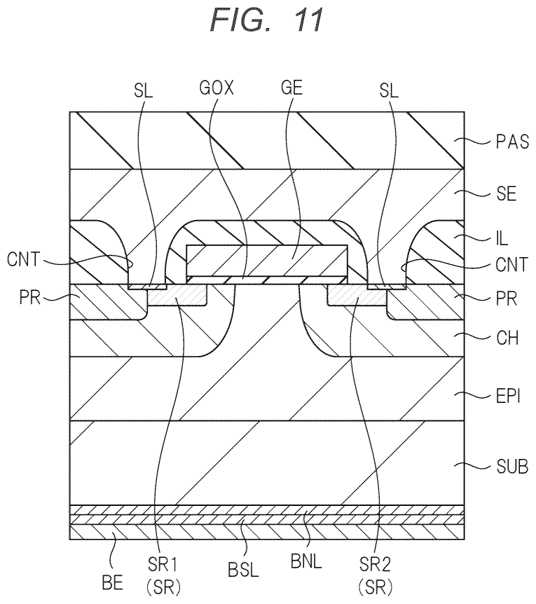

FIG. 11 is a cross-sectional view showing the configuration of a semiconductor device including a planar type SiC field effect transistor. In FIG. 11, the semiconductor device has a silicon carbide semiconductor substrate SUB, a backside high concentration semiconductor layer BNL, a backside silicide BSL, and a bottom electrode BE. The semiconductor device also has an epitaxial layer EPI, a channel layer CH, a source region SR, a body contact region PR, and a metal silicide SL. Furthermore, the semiconductor device has a gate insulating film GOX, a gate electrode GE, an interlayer insulating film IL, a source electrode SE, and a passivation film PAS.

The silicon carbide semiconductor substrate SUB is, for example, an n+ type semiconductor substrate. On a bottom side of the silicon carbide semiconductor substrate SUB, the backside high concentration semiconductor layer BNL made of an n+ type semiconductor layer is formed, for example, the backside silicide BSL is formed so as to contact this backside high concentration semiconductor layer BNL. The backside silicide BSL is composed of, for example, nickel silicide. And a bottom electrode BE is formed so as to contact this backside silicide BSL. The bottom electrode BE is composed of, for example, a laminated film made of a titanium film, a nickel film, and a gold film.

Next, the epitaxial layer EPI is formed on an upper surface of the silicon carbide semiconductor substrate SUB. The epitaxial layer EPI is made of, for example, an n-type semiconductor layer. Inside the epitaxial layer EPI, a plurality of channel layers CH made of, for example, a p-type semiconductor layer are formed so as to be separated from each other. And the source region SR and the body contact region PR that contact each other are formed inside each of the plurality of channel layers CH.

Therefore, as shown in FIG. 11, a plurality of source regions SR and a plurality of body contact regions PR are formed in the semiconductor device. For example, in FIG. 11, a source region SR1 and a source region SR2 included in the plurality of source regions SR are shown. Each of the plurality of source regions SR is composed of, for example, an n+ type semiconductor region. Each of the plurality of body contact regions PR is composed of, for example, a p+ type semiconductor region.

Next, as shown in FIG. 11, the gate insulating film GOX is formed on an upper surface of the epitaxial layer EPI between the source region SR1 and the source region SR2. In detail, the gate insulating film GOX is formed on the upper surface of the epitaxial layer EPI, on an upper surface of the channel layer CH, on a part of the source region SR1, and on a part of the source region SR2.

The gate insulating film GOX is composed of the gate insulating film described in the embodiment. That is, the gate insulating film GOX is composed of an aluminum oxide film formed by using AlCl₃ as a material gas of an ALD method. As a result, the gate insulating film GOX has a halogen element (chlorine) with a higher concentration than carbon.

A gate electrode GE is formed on the gate insulating film GOX. The gate electrode GE is composed of a polysilicon film into which an n-type impurity (donor) such as phosphorus (P) or arsenic (As) has been introduced. The interlayer insulating film IL is formed so as to cover the gate electrode GE. The interlayer insulating film IL is composed of a silicon oxide film, for example.

In the interlayer insulating film IL thus configured, a contact hole CNT reaching the source region SR and the body contact region PR is formed. On a surface of the source region SR and the body contact region PR exposed from a bottom surface of the contact hole CNT, a metal silicide SL is formed. The metal silicide SL is composed of nickel silicide, for example. The source electrode SE is formed to fill the inside of the contact hole CNT and on the interlayer insulating film IL. As a result, the source electrode SE is electrically connected to the source region SR and the body contact region PR. The source electrode SE is composed of a laminated film consisting of a titanium film, a titanium nitride film, and an aluminum film, for example. The passivation film PAS is formed on the source electrode SE. The passivation film PAS is composed of a polyimide resin film, for example.

In this way, the semiconductor device in Application Example 1 is configured.

In the semiconductor device of Application Example 1, the gate insulating film described in the embodiment is used. Therefore, the gate insulating film GOX of the semiconductor device becomes a gate insulating film with high reliability. As a result, according to the semiconductor device in Application Example 1, reliability can be improved.

### (A Manufacturing Method of the Semiconductor Device)

Next, a manufacturing method of the semiconductor device in Application Example 1 will be described.

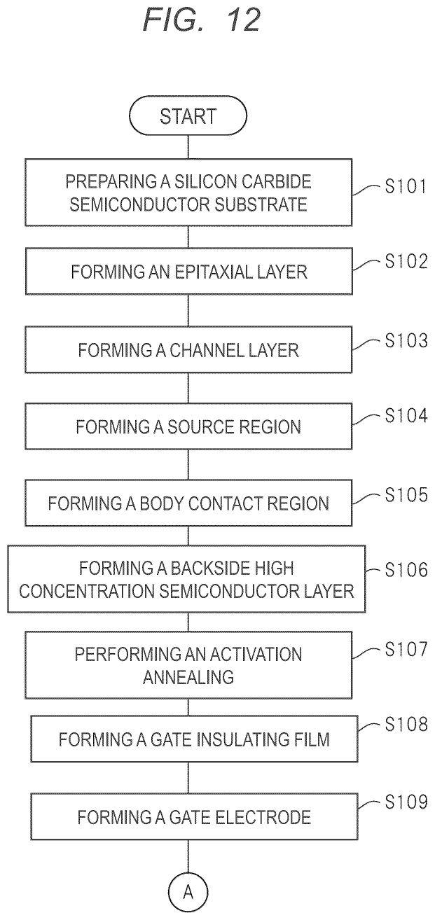

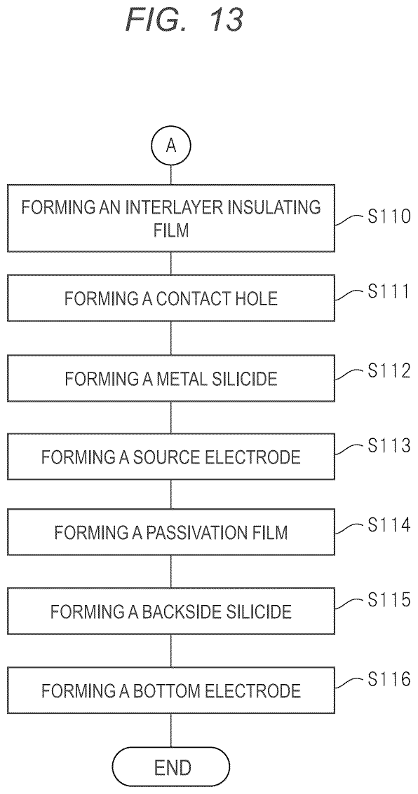

FIGS. 12 and 13 are flowcharts showing the manufacturing process of the semiconductor device in Application Example 1. First, the silicon carbide semiconductor substrate SUB is prepared (S101). Next, an epitaxial layer EPI is formed on the upper surface of the silicon carbide semiconductor substrate SUB (S102). The epitaxial layer EPI is an n-type semiconductor layer. The epitaxial layer EPI is formed by growing a silicon carbide layer into which an n-type impurity such as nitrogen has been introduced using an epitaxial growth method.

Next, the channel layer CH is formed inside the epitaxial layer EPI by using photolithography technology and ion implantation method (S103). The channel layer CH is a p-type semiconductor layer. The channel layer CH is formed by introducing a p-type impurity such as aluminum into the epitaxial layer EPI. Then, the source region SR is formed inside the channel layer CH by using photolithography technology and ion implantation method (S104). The source region SR is an n+ type semiconductor region. The source region SR is formed by introducing an n-type impurity such as nitrogen into the channel layer CH.

Subsequently, the body contact region PR in contact with the source region SR is formed inside the channel layer CH by using photolithography technology and ion implantation method (S105). The body contact region PR is a p+ type semiconductor region. The body contact region PR is formed by introducing a p-type impurity such as aluminum into the channel layer CH. Then, the backside high concentration semiconductor layer BNL is formed on the bottom surface of the silicon carbide semiconductor substrate SUB by using an ion implantation method (S106). The backside high concentration semiconductor layer BNL is an n+ type semiconductor layer. The backside high concentration semiconductor layer BNL is formed, for example, by introducing n-type impurities such as nitrogen into the silicon carbide semiconductor substrate SUB.

Next, the silicon carbide semiconductor substrate SUB is heated to perform activation annealing (S107). The activation annealing is performed, for example, by heating the silicon carbide semiconductor substrate SUB to 1700 degrees Celsius. By this activation annealing, the conduction type impurities introduced into the channel layer CH, the source region SR, the body contact region PR and the backside high concentration semiconductor layer BNL formed by the ion-implantation method are activated.

Subsequently, the gate insulating film GOX is formed on the upper surface of the epitaxial layer EPI, which has formed the channel layer CH, the source region SR, and the body contact region PR (S108). The gate insulating film GOX is formed by the ALD method using AlCl₃ as the material gas. As a result, the gate insulating film GOX is composed of an aluminum oxide film.

As described in the embodiment, the aluminum oxide film formed by the ALD method using AlCl₃ has a small defect level density and leakage current density, and is a high-quality film. Therefore, the gate insulating film GOX becomes the gate insulating film with high reliability.

Here, after forming the gate insulating film GOX, it is effective to heat the silicon carbide semiconductor substrate SUB at a temperature lower than 900 degrees Celsius, which is higher than a formation temperature of the gate insulating film GOX. This is because, by this heating process, moisture can be desorbed from the gate insulating film GOX at a temperature at which the silicon carbide semiconductor substrate SUB is not oxidized (a temperature lower than 900 degrees Celsius).

Subsequently, the gate electrode GE is formed on the gate insulating film GOX (S109). The gate electrode GE can be formed by using CVD method and patterning technology. Specifically, the gate electrode GE can be formed by depositing a polysilicon film doped with n-type impurities such as nitrogen, and then patterning this polysilicon film by photolithography and etching techniques.

Then, an interlayer insulating film IL is formed on the upper surface of the epitaxial layer EPI, which has formed the channel layer CH, the source region SR, and the body contact region PR, so as to cover the gate electrode GE (S110). The interlayer insulating film IL is composed of, for example, a silicon oxide film. The silicon oxide film can be formed by using the CVD method.

Next, the contact hole CNT is formed in the interlayer insulating film IL by using photolithography and etching techniques (S111). The contact hole CNT is formed so as to reach both the source region SR and the body contact region PR by penetrating the interlayer insulating film IL.

Subsequently, the metal silicide SL is formed on the surface of the source region SR and the body contact region PR exposed from the bottom surface of the contact hole CNT (S112). The metal silicide SL is composed of, for example, nickel silicide. Nickel silicide can be formed by forming a nickel film on the interlayer insulating film IL including the bottom surface of the contact hole CNT, and then performing a silicide annealing at 1000 degrees Celsius on the silicon carbide semiconductor substrate SUB. As mentioned above, it is desirable to remove moisture from the gate insulating film GOX by heating the silicon carbide semiconductor substrate SUB after forming the gate insulating film GOX. That is, a heating process for removing moisture from the gate insulating film GOX may be performed after forming the gate insulating film GOX. In this case, the moisture in the gate insulating film GOX is removed at the stage of performing the silicide annealing. Therefore, oxidation of the silicon carbide semiconductor substrate SUB can be suppressed by the silicide annealing.

However, the above-mentioned heating process after forming the gate insulating film GOX can also be substituted with the silicide annealing. In other words, it is permissible to remove moisture from the gate insulating film GOX by the silicide annealing, without performing a heat treatment process after forming the gate insulating film GOX. Thus, not only the function of forming the metal silicide SL, but also the function of removing moisture from the gate insulating film GOX can be shared by the silicide annealing.

In this case, since the temperature of the silicide annealing is higher than the oxidation temperature of silicon carbide, the moisture that departs and the silicon carbide oxidize by the silicide annealing. Therefore, when removing moisture from the gate insulating film GOX by the silicide annealing, it is important to sufficiently reduce the moisture contained in the gate insulating film GOX by adjusting the film formation conditions when forming the gate insulating film GOX.

Subsequently, the inside of the contact hole CNT, which has formed the metal silicide SL on the bottom surface, is filled, and the source electrode SE is formed on the interlayer insulating film IL (S113). The source electrode SE is composed of a laminated film consisting of, for example, a titanium film, a titanium nitride film, and an aluminum film. The source electrode SE can be formed, for example, by using a sputtering method. Then, the passivation film PAS is formed on the source electrode SE (S114). The passivation film PAS is a surface protection film. The passivation film PAS is composed of, for example, a polyimide resin film. The polyimide resin film can be formed, for example, by a coating method.

Next, the backside silicide BSL that contacts the backside high-concentration semiconductor layer BNL formed on the bottom surface of the silicon carbide semiconductor substrate SUB is formed (S115). The backside silicide BSL is composed of, for example, nickel silicide. Nickel silicide can be formed by forming a nickel film that contacts the backside high-concentration semiconductor layer BNL and then performing the silicide annealing, which is a heat treatment at 1000 degrees Celsius, on the silicon carbide semiconductor substrate SUB.

Subsequently, the bottom electrode BE that contacts the backside silicide BSL is formed (S116). The bottom electrode BE is composed of a laminated film consisting of, for example, a titanium film, a nickel film, and a gold film. The bottom electrode BE can be formed, for example, by using a sputtering method.

In this way, the semiconductor device in Application Example 1 can be manufactured. In the semiconductor device of Application Example 1, an aluminum oxide film formed by the ALD method using AlCl₃ is used. Therefore, the gate insulating film GOX of the semiconductor device in Application Example 1 becomes the gate insulating film with high reliability. As a result, the reliability can be improved according to the semiconductor device in Application Example 1.

### Application Example 2

### (Configuration of a Semiconductor Device)

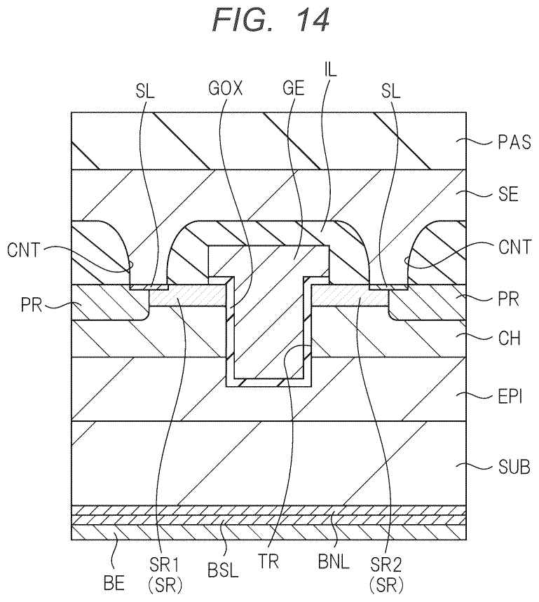

FIG. 14 is a cross-sectional view showing the configuration of a semiconductor device including a trench gate type SiC field effect transistor. In FIG. 14, the semiconductor device has a silicon carbide semiconductor substrate SUB, a backside high-concentration semiconductor layer BNL, a backside silicide BSL, and a bottom electrode BE. In addition, the semiconductor device has an epitaxial layer EPI, a channel layer CH, a source region SR, a body contact region PR, and a metal silicide SL. Furthermore, the semiconductor device has a trench TR, a gate insulating film GOX, a gate electrode GE, an interlayer insulating film IL, a source electrode SE, and a passivation film PAS.

The silicon carbide semiconductor substrate SUB is, for example, an n+ type semiconductor substrate. On a bottom surface of the silicon carbide semiconductor substrate SUB, the backside high-concentration semiconductor layer BNL composed of, for example, an n+ type semiconductor layer is formed. The backside silicide BSL is formed so as to contact this backside high-concentration semiconductor layer BNL. The backside silicide BSL is composed of, for example, nickel silicide. Then, the bottom electrode BE is formed so as to contact the backside silicide BSL. The bottom electrode BE is composed of a laminated film consisting of, for example, a titanium film, a nickel film, and a gold film.

Next, an epitaxial layer EPI is formed on an upper surface of the silicon carbide semiconductor substrate SUB. The epitaxial layer EPI is, for example, composed of an n-type semiconductor layer. The channel layer CH, which is, for example, composed of a p-type semiconductor layer, is formed on the epitaxial layer EPI. Inside the channel layer CH, a plurality of source regions SR and a plurality of body contact regions PR are formed. For example, FIG. 14 shows a source region SR1 and a source region SR2 included in the plurality of source regions SR. Each of the plurality of source regions SR is, for example, composed of an nt type semiconductor region. Also, each of the plurality of body contact regions PR is, for example, composed of a p+ type semiconductor region.

Next, as shown in FIG. 14, the trench TR is formed between the source region SR1 and the source region SR2. This trench TR is formed to penetrate the channel layer CH. The bottom of the trench TR reaches inside the epitaxial layer EPI.

The gate insulating film GOX is formed on an inner wall of the trench TR. This gate insulating film GOX is composed of the gate insulating film described in the embodiment. That is, the gate insulating film GOX is composed of an aluminum oxide film formed using AlCl₃. As a result, the gate insulating film GOX has a halogen element (chlorine) with a higher concentration than carbon.

Next, the gate electrode GE is embedded in the trench TR through the gate insulating film GOX. This gate electrode GE is formed to have a portion embedded in the trench TR and a portion protruding above the trench TR. The gate electrode GE is, for example, composed of a polysilicon film into which n-type impurities (donors) such as phosphorus (P) and arsenic (As) have been introduced. The interlayer insulating film IL is formed to cover the channel layer CH on which the source region SR and the body contact region PR are formed and the gate electrode GE. The interlayer insulating film IL is, for example, composed of a silicon oxide film.

In the interlayer insulating film IL configured as described above, a contact hole CNT reaching the source region SR and the body contact region PR is formed. The metal silicide SL is formed on a surface of the source region SR and the body contact region PR exposed from a bottom surface of the contact hole CNT. The metal silicide SL is, for example, composed of nickel silicide. Then, the source electrode SE is formed to fill the inside of the contact hole CNT and on the interlayer insulating film IL. As a result, the source electrode SE is electrically connected to the source region SR and the body contact region PR. The source electrode SE is, for example, composed of a laminated film consisting of a titanium film, a titanium nitride film, and an aluminum film. The passivation film PAS is formed on the source electrode SE. The passivation film PAS is, for example, composed of a polyimide resin film.

In this way, the semiconductor device in Application Example 2 is configured.

Even in the semiconductor device of Application Example 2, the gate insulating film described in the embodiment is used. Therefore, the gate insulating film GOX of the semiconductor device becomes the gate insulating film with high reliability. As a result, according to the semiconductor device in Application Example 2, reliability can be improved.

### (A Manufacturing Method of the Semiconductor Device)

Next, a manufacturing method of the semiconductor device in Application Example 2 will be described. Note that the manufacturing method of the semiconductor device in Application Example 2 is almost the same as the manufacturing method of the semiconductor device in Application Example 1, so the same steps are omitted and the different steps are mainly described. In particular, the manufacturing method of the semiconductor device in Application Example 2 will be described using FIGS. 12 and 13.

In FIG. 12, the steps from S101 to S107 are omitted because they are the same as the manufacturing method of the semiconductor device in Application Example 1.

Next, the trench TR is formed using photolithography and etching techniques. The trench TR is formed to penetrate the channel layer CH, which has formed the source region SR and the body contact region PR, so that the bottom of the trench TR reaches inside the epitaxial layer EPI (see FIG. 14).

Subsequently, the gate insulating film GOX is formed on the channel layer CH, which has formed the source region SR and the body contact region PR, and on the inner wall of the trench TR (S108). The gate insulating film GOX is formed by the ALD method using AlCl₃ as a material gas. As a result, the gate insulating film GOX is composed of an aluminum oxide film.

As described in the embodiment, the aluminum oxide film formed by the ALD method using AlCl₃ has a small defect level density and leakage current density, and is a high-quality film. Therefore, the gate insulating film GOX becomes a high-quality gate insulating film with high reliability.

Afterwards, the gate electrode GE, which has a portion filling the trench TR through the gate insulating film GOX and a portion protruding above the trench TR, is formed (S109). The gate electrode GE can be formed using a CVD method and patterning techniques. Specifically, the gate electrode GE can be formed by depositing a polysilicon film, to which an n-type impurity such as nitrogen has been added, on the channel layer CH, which has formed the source region SR and the body contact region PR, and inside the trench TR, and then patterning this polysilicon film using photolithography and etching techniques.

The steps from S110 to S116 shown in FIG. 13 are omitted because they are the same as in Application Example 1. In this way, the semiconductor device in Application Example 2 can be manufactured. In the semiconductor device of Application Example 2, an aluminum oxide film formed by the ALD method using AlCl₃ is used. Therefore, the gate insulating film GOX of the semiconductor device in Application Example 2 becomes the high-quality gate insulating film with high reliability. As a result, the reliability can be improved according to the semiconductor device in Application Example 2.

The invention made by the present inventor has been described above in detail based on the embodiment, but the present invention is not limited to the embodiment described above, and it is needless to say that various modifications can be made without departing from the gist thereof.

What is claimed is:

1. A manufacturing method of a semiconductor device, comprising the step of:
(a) forming a gate insulating film on a semiconductor substrate composed of a wide band gap semiconductor material with a larger band gap than silicon, wherein
in the step of (a), the gate insulating film is formed by a chemical vapor deposition method using a material gas containing a halogen element and a metal element.

2. The manufacturing method of the semiconductor device according to claim 1, wherein
the halogen element is chlorine.

3. The manufacturing method of the semiconductor device according to claim 1, wherein
the material gas does not contain carbon and hydrogen.

4. The manufacturing method of the semiconductor device according to claim 1, wherein
the material gas is AlCl₃ gas.

5. The manufacturing method of the semiconductor device according to claim 1, wherein
in the step of (a), a formation temperature is 25 degrees Celsius or more and 400 degrees Celsius or less.

6. The manufacturing method of the semiconductor device according to claim 1, wherein
the chemical vapor deposition method is an atomic layer deposition method, and
the atomic layer deposition method comprising the steps of:
(a1) introducing a first material gas containing the halogen element,
(a2) purging the first material gas,
(a3) introducing a second material gas containing oxygen, and
(a4) purging the second material gas.

7. The manufacturing method of the semiconductor device according to claim 6, wherein
the first material gas is AlCl₃ gas, and
the second material gas is one of H₂O gas, O₃ gas) or N₂O gas.

8. The manufacturing method of the semiconductor device according to claim 1, further comprising the step of:
(b) after the step of (a), heating the semiconductor substrate.

9. The manufacturing method of the semiconductor device according to claim 8, wherein
a heating temperature in the step of (b) is higher than a formation temperature of the gate insulating film in the step of (a).

10. The manufacturing method of the semiconductor device according to claim 9, wherein
the heating temperature is 500 degrees Celsius or more and less than 900 degrees Celsius.

11. The manufacturing method of the semiconductor device according to claim 8, wherein
the step (b) is a silicide annealing process for forming a metal silicide.

12. A semiconductor device comprising:
a field effect transistor having a gate insulating film formed on a semiconductor substrate composed of a wide band gap semiconductor material with a larger band gap than silicon, wherein
the gate insulating film has a halogen element with a higher concentration than carbon.

13. The semiconductor device according to claim 12, wherein the halogen element is chlorine.

14. The semiconductor device according to claim 12, wherein
the field effect transistor includes:
a bottom electrode formed on a bottom surface of the semiconductor substrate,
an epitaxial layer formed on an upper surface opposite to the bottom surface of the semiconductor substrate,
a plurality of source regions including a first source region and a second source region formed in the epitaxial layer, and
a gate electrode, wherein
the gate insulating film is formed between the first source region and the second source region on an upper surface of the epitaxial layer in plan view, and
the gate electrode is formed on the gate insulating film.

15. The semiconductor device according to claim 12, wherein the field effect transistor includes:
a bottom electrode formed on a bottom surface of the semiconductor substrate,
a source region formed in an upper surface of the semiconductor substrate,
a trench formed in the upper surface of the semiconductor substrate such that the trench penetrates through the source region,
a gate insulating film formed on an inner wall of the trench, and
a gate electrode including a portion filled in the trench via the gate insulating film.
